(19) United States
(12) Patent Application Publication
(10) Pub. No.: US 2012/0040288 A1
(43) Pub. Date: Feb. 16, 2012

(54) Epoxy formulations with controllable photospeed

(75) Inventors: Timothy Adams, Sudbury, MA (US); Manuel doCanto, Stoughton, MA (US); George Cernigliaro, Northborough, MA (US)

(73) Assignee: MicroChem Corp.

(21) Appl. No.: 12/806,372

(22) Filed: Aug. 11, 2010

(51) Int. Cl. G03F 7/004

(52) U.S. Cl. 430/270.1

(57) ABSTRACT

The present invention is directed to an epoxy film composition, comprising: novolac resin; solvent; a photoacid generator having the structure A⁺B⁻ and having a pKa of −5 or less; and a photolabile quencher generator having the structure C⁺D⁻ and having a pKa greater than −10; wherein B⁻ and D⁻ are different; wherein the amount of the photoacid generator ranges from 0.1 to 7 wt %, based on the total weight of the composition; and wherein the amount of the photolabile quencher generator ranges from 0.1 to 20 wt %, based on the total weight of the photoacid generator. The present invention is also directed to a method of controlling photospeed in a negative photoresist.

### BACKGROUND OF THE INVENTION

1. Field of the Invention

The present invention is directed to permanent epoxy film compositions, and more particularly to such permanent epoxy film compositions that utilize, among other things, a combination of a photoacid generator and a photolabile quencher generator that together modulate the photospeed of an epoxy photoresist.

2. Brief Description of the Related Art

Photoimageable coatings are currently used in a wide variety of semiconductor and micromachining applications. In such applications, photoimaging is accomplished by exposing the coating on a substrate to patterned radiation thereby inducing a solubility change in the coating such that the exposed or unexposed regions can be selectively removed by treatment with a suitable developer composition. The photoimageable coating (such as photoresist) may be either of the positive or negative type, where exposure to radiation either respectively increases or decreases film solubility in the developer. Advanced electronic packaging applications requiring high density interconnects with a high aspect ratio (defined as the height to width ratio of the imaged feature), or applications involving the fabrication of micro-electromechanical devices (MEMS) often require photoimageable layers capable of producing uniform films and high aspect ratio images with vertical sidewall profiles in films with a thickness greater than one hundred microns.

One important characteristic of a photoimageable coating is its sensitivity or photospeed, which is defined as the exposure energy required to activate the photoactive component and generate a sufficient amount of photoacid to provide the desired solubility differential between exposed and unexposed areas of a photoresist coating layer. Typical units for photospeed are mJ/cm² or J/cm². More specifically, photospeed can be described as the dose energy (irradiation) required to size a particular feature. In most applications, photospeed must be within an acceptable and consistent range or value to permit desired processing of the resist. For instance, sufficiently fast photospeed is important in many processes where a number of exposures are needed, such as in generating multiple patterns by a step and repeat process, or where activating radiation of reduced intensity is employed. Sufficiently high photospeed also permits reduction in the concentration of the radiation sensitive component in the photoresist. On the other hand, a resist that is “too fast”, i.e. has too high photospeed, also can be undesirable. For example, extremely fast photospeed may compromise resolution of the patterned image, or exposure equipment may not be well suited to image such a fast photopatterning film.

During the manufacture of chemically amplified patterning materials, it is common practice to modify the formulation in order to meet specification for photospeed. Several approaches are known for modifying photospeed to a desired range or value. For example, for deep UV and 193 nm resists, variations are made to the base loadings in order to vary the photospeed (increased base loading for slower photospeed, decreased base loading for faster photospeed). U.S. Pat. Nos. 5,879,856 and 6,300,035 describe this approach. For negative resists based on epoxy resins, where the glycidyl ether group is polymerized during cure, the preferred curing agents are onium salt photoacid generators (PAGs) which support cationic polymerization of the epoxy resin. However, the addition of a base to these resist formulations is not preferred due to shelf life issues (epoxy resins will also cure under basic conditions). Another possible approach for controlling photospeed is to blend onium salt PAG's of differing photo sensitivities. However, a problem with this approach results from different PAG's which vary by having different cations having significantly different extinction coefficients at the exposing wavelength. These differences in extinction coefficients can lead to not only differences in photospeed but also to significant differences in image fidelity and wall angle in the finished products. This is especially true for thick permanent films such as SU-8, where photoacid generator absorbance attenuates light (and consequently the amount of acid generation) through the film. Variations in sidewall profile from lot to lot of product are undesirable attributes for most photoresist users.

What is needed in the art are compositions and methods where the user can control the photospeed of an epoxy resist composition in a predictable manner, and without the disadvantages outlined above. The present invention is believed to answer that need.

### SUMMARY OF THE INVENTION

In one aspect, the present invention is directed to an epoxy film composition, comprising: novolac resin; solvent; a photoacid generator having the structure A⁺B⁻ and having a pKa of −5 or less; and a photolabile quencher generator having the structure C⁺D⁻ and having a pKa greater than −10; wherein B⁻ and D⁻ are different; wherein the amount of the photoacid generator ranges from 0.1 to 7 wt %, based on the total weight of the composition; and wherein the amount of the photolabile quencher generator ranges from 0.1 to 20 wt %, based on the total weight of the photoacid generator.

In another aspect, the present invention is also directed to a method for controlling photospeed of a chemically amplified negative photoresist, comprising the steps of: (a) providing a negative photoresist composition comprising novolac resin; solvent; a photoacid generator having the structure A⁺B⁻ and having a pKa of −5 or less; a photolabile quencher generator having the structure C⁺D⁻ and having a pKa greater than −10; wherein B⁻ and D⁻ are different; wherein the amount of the photoacid generator ranges from 0.1 to 10 wt %, based on the total weight of the novolac resin; and wherein the amount of the photolabile quencher generator ranges from 0.1 to 20 wt %, based on the total weight of the photoacid generator; and (b) selecting a desired photospeed for the negative photoresist and adjusting the amount of the photolabile quencher generator in the photoresist composition to achieve the desired photospeed.

This and other aspects of the invention will become apparent from the following detailed description of the invention.

### BRIEF DESCRIPTION OF THE DRAWINGS

The invention will be better understood from the following detailed description and accompanying drawings, in which:

FIG. 1 is a graph showing slower photospeed as a function of increasing amounts of quencher;

FIG. 2 is another graph showing slower photospeed as a function of increasing amounts of a quencher; and

FIG. 3 is a graph showing that absorbance remains constant as photospeed is modulated.

### DETAILED DESCRIPTION OF THE INVENTION

As indicated above, controlling photospeed in epoxy film compositions is desirable, but technically challenging for several reasons. First, photospeed modulating components must be chemically compatible with the other formulation components and not affect shelf life of the composition product. Second, the photospeed modulating component must not negatively impact image fidelity or the structure of the final product. In this invention, the inventors have discovered that the photospeed of a photoresist composition can be controlled by blending a photoacid generator (PAG) and a photolabile quencher generator (PQG), each of which has a defined pKa range. Addition of the PQG moderates the photospeed of the PAG in a controllable way by quenching a portion of the acid generated by the PAG. As defined herein, photospeed is the exposure energy required to activate the photoactive component and generate a sufficient amount of photoacid to provide the desired solubility differential between exposed and unexposed areas of a coating layer. Typical units for photospeed are mJ/cm² or J/cm². More specifically, photospeed can be described as the dose of energy required to size a particular feature. In the Examples that follow, the sizing dose, or photospeed, was the dose required to obtain a 10 micron line at a 1:1 pitch.

According to the present invention, the photospeed of photopatterning epoxy compositions can be controlled through use of a photoacid generator (PAG) and photolabile quencher generator (PQG) combination. While not wishing to be bound by any particular theory, it is believed that these selected PAG/PQG combinations allow interplay of pKa differences arising from each of these components following exposure and before post-exposure bake (PEB). Photogenerated superacid from exposure of the PAG is immediately quenched by the stronger base from the photolabile quencher generator. As only the stronger protonic acid reacts with epoxy, the photogenerated quencher therefore becomes spectator, not influencing the curing reaction. As a mole % excess of PAG is normally employed, an excess of the superacid is produced by the PAG, and only that excess is available for PEB-based amplification to harden the epoxy film. The extent of the pKa differences between the conjugate bases should govern how responsive is the modulation of superacid. The larger the pKa difference, the greater the change in lithographic/cure dose as a function of wt % added PQG. As defined herein, pKa (or acid dissociation constant) is the negative log (base 10) of the dissociation constant of the a polar compound in aqueous solution at room temperature. The larger the value of pKa, the smaller the extent of dissociation. As a general rule, a weak acid has a pKa value in the approximate range of −2 to 12 in water. Acids with a pKa value of less than about −2 are said to be strong acids.

Accordingly, the present invention is directed to an epoxy film composition, comprising: novolac resin, solvent, a photoacid generator having the structure A⁺B⁻, and a photolabile quencher generator having the structure C⁺ D⁻. The photoacid generator has a pKa of −5 or less and ranges from 0.1 to 7 wt %, based on the total weight of the composition. The photolabile quencher generator has a pKa greater than −10 and ranges from 01 to 20 wt %, based on the total weight of the photoacid generator. Each of these features and components is described in more detail below.

The first component of the composition of the invention is a novolac resin. While any novolac resin may be used in the compositions and methods of the present invention, bisphenol-A novolac epoxy resins are preferred, and can be obtained by known methods such as reacting a bisphenol A novolac resin and epichlorohydrin. Resins having a weight average molecular weight ranging from 2000 to 11000 are preferred and resins with a weight average molecular weight ranging from 4000 to 7000 are particularly preferred. EPICOAT 157 (epoxide equivalent weight of 180 to 250 grams resin per equivalent of epoxide (g resin/eq or g/eq) and a softening point of 80-90° C.) made by Japan Epoxy Resin Co., Ltd. Tokyo, Japan, and EPON SU-8 Resin (epoxide equivalent weight of 195 to 230 g/eq and a softening point of 80 to 90° C.) made by Resolution Performance Products, Houston, Tex. and the like are cited as preferred examples of bisphenol A novolac epoxy resins suitable for use in the present invention. Other co-resins, particularly those that contain glycidyl ether moieties or phenols could also be used. The presence of the glycidyl ether or phenol functionality have the advantage of being able to crosslink into the backbone of the cured polymer. Examples include a formaldehyde polymer with (chloromethyl)oxirane and phenol resin (Nippon Kayaku, Tokyo, Japan) and diglycidyl ether of propylene glycol (Asahi Denka, Tokyo, Japan) which are described in the examples in this application. The preferred amount of novolac ranges from about 40-80 wt % of total solids, based on the total weight of the composition.

The second component of the composition of the invention is a solvent or combination of solvents. In practice, any common photoresist or permanent film solvent may be used. Examples of suitable solvents include acetone, 2-butanone, 2-pentanone, 3-pentanone, methyl isobutyl ketone, methyl t-butyl ketone, cyclopentanone, cyclohexanone, dipropylene glycol dimethyl ether, dipropylene glycol diethyl ether, tetrahydrofuran, 1,3-dioxolane, 1,4-dioxane, dimethoxyethane, diglyme, triglyme, ethyl acetate, butyl acetate, butyl cellosolve acetate, carbitol acetate, propylene glycol monomethyl ether acetate, gamma-butyrolactone, toluene, xylene, tetramethylbenzene, octane, decane, anisole, as well as combinations of two, three, four, or more of these solvents. Preferably, the solvent component comprises from 10 to 80% by weight, and preferably from 20 to 60% by weight, based on the total weight of the composition.

The third component of the composition of the invention is a photoacid generator (PAG) which is a compound that generates an acidic species when irradiated with active rays, such as X-rays, UV radiation, light, and the like. The PAG used in the composition of the invention is generally ionic, and has the general structure A⁺B⁻, where A⁺ is the cationic species and B⁻ is the anionic species.

Suitable cationic species (A⁺) include aromatic onium cations, such as aromatic sulfonium cation, aromatic iodonium cation, indolinium cation, as well as various combinations of these. Photoacid generators based on sulfonium or iodonium salts are well-known and have been extensively discussed in the literature (see for example. Crivello et al., “Photoinitiated Cationic Polymerization with Triarylsulfonium Salts”, Journal of Polymer Science: Polymer Chemistry Edition, vol. 17, pp. 977-999 (1979)).

Generally, preferred structures for the cationic species include (Aryl)₃S⁺, (Aryl)₂(Alkyl)S⁺, (Aryl)(Alkyl)₂S⁺, and (Aryl)₂I⁺ where aryl is any structure containing at least one aromatic group. Specific examples of preferred cationic species (A⁺) include the following structures I-V:

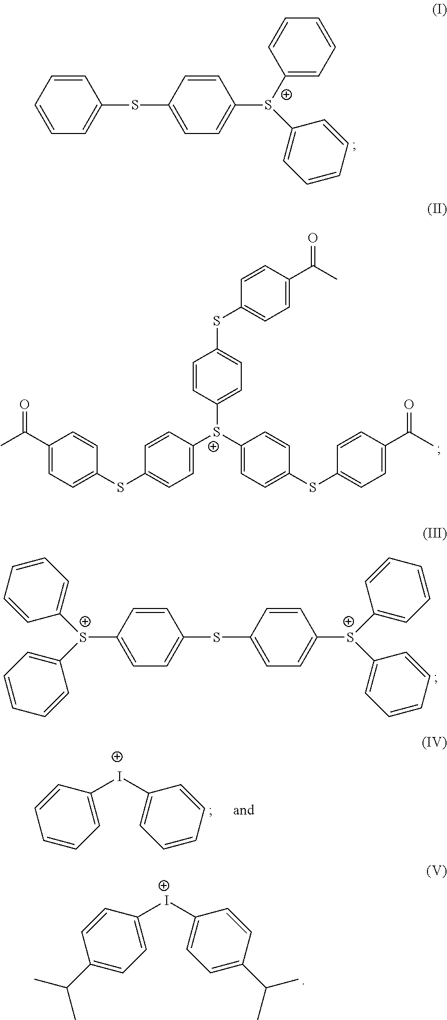

As a general requirement, the cationic species of the photoacid generators used in the present invention should have equivalent (e.g., less than ±10% (absorbance) at the wavelength of exposure) or identical extinction coefficients at the wavelength of exposure.

Examples of anionic component B⁻ include SbF₆⁻, BF₄⁻, PF₆⁻, AsF₆⁻, (CF₃SO₂)₃C⁻, (CF₃CF₂)₃PF₃⁻, (C₆F₅)₄B⁻, CF₃SO₃⁻. The PAG component should have a pKa of −5 or less, and more preferably a pKa of −20 or less. Moreover, useful amounts of the PAG component in the composition range from 0.1 to 10 wt %, based on the total weight of the novolac resin, and more preferably from 0.5 to 5 wt %, based on the total weight of the novolac resin.

Examples of preferred photoacid generators having the A⁺B⁻ ionic structure include the following:

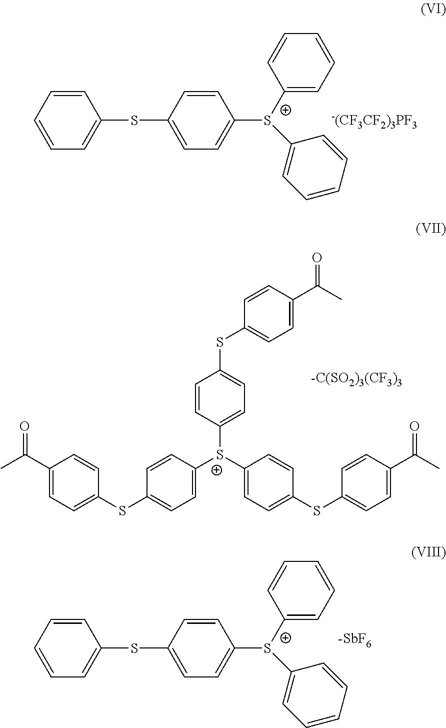

The fourth component of the composition of the invention is a photolabile quencher generator (PQG) which is a compound that generates a quenching species when irradiated with active rays, such as X-rays, UV radiation, light, and the like. The PQG used in the composition of the invention is generally ionic, and has the general structure C⁺D⁻, where C⁺ is the cationic species and D⁻ is the anionic species.

Suitable cationic species (C⁺) are generally the same as the cationic (A⁺) species outlined above, and include aromatic onium cations, such as aromatic sulfonium cation, aromatic iodonium cation, indolinium cation, as well as various combinations of these. Generally, preferred structures for the cationic species (C⁺) include (Aryl)₃S⁺, (Aryl)₂(Alkyl)S⁺, (Aryl)(Alkyl)₂S⁺, and (Aryl)₂I⁺ where aryl is any structure containing at least one aromatic group. Specific examples of preferred cationic species (C⁺) include the structures I-V shown above.

Examples of anionic component D⁻ include RSO₃⁻ where R is an alkyl group having 1-10 carbon atoms, and

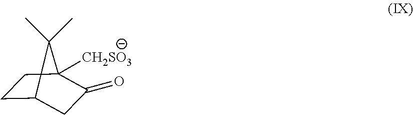

Examples of useful RSO₃⁻ species include methane (CH₃SO₃⁻), ethane sulfonate (C₂H₅SO₃⁻), propane sulfonate (C₃H₇SO₃⁻), and butane sulfonate (C₄H₉SO₃⁻). In one embodiment, (IX) is selected due to its size and propensity to not diffuse through the film product.

The PQG component should have a pKa of −10 or greater, and more preferably a pKa of 1 or greater. Moreover, useful amounts of the PQG component in the composition range from 0.1 to 20 wt %, based on the total weight of the PAG, and more preferably from 1 to 10 wt %, based on the total weight of the PAG.

In the composition of the invention, the photoacid generator and the photolabile quencher generator may have the same cation species (A⁺ and C⁺) but must have different anion species (B⁻ and D⁻). In other words, the cationic species in the photoacid generator and the photolabile quencher generator may be the same or different. Further, it is preferable, but not required, that the cationic species of the photoacid generator and the photolabile quencher generator have similar or identical extinction coefficients.

Examples of preferred photolabile quencher generators having the C⁺B⁻ ionic structure include the following:

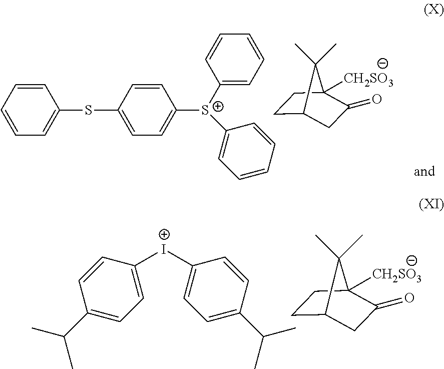

Optionally, it may be beneficial in certain embodiments to use an additional epoxy resin in the composition. Depending on its chemical structure, optional epoxy resin may be used to adjust the lithographic contrast of the composition or to modify the optical absorbance of the film. The optional epoxy resin may have an epoxide equivalent weight ranging from 150 to 250 grams resin per equivalent of epoxide. Examples of optional epoxy resins suitable for use include EOCN 4400, an epoxy cresol-novolac resin with an epoxide equivalent weight of about 195 g/eq manufactured by Nippon Kayaku Co., Ltd., Tokyo, Japan; or cycloaliphatic epoxies as disclosed in U.S. Pat. Nos. 4,565,859 and 4,481,017 wherein vinyl substituted alicyclic epoxide monomers are copolymerized with a compound containing a least one active hydrogen atom to produce a vinyl substituted polyether that is subsequently oxidized with a peracid to produce the alicyclic epoxy resin. A preferred commercial example is EHPE 3150 epoxy resin which has an epoxide equivalent weight of 170 to 190 g/eq and is manufactured by Daicel Chemical Industries, Ltd., Osaka, Japan. When an optional epoxy resin is used, the amount of resin that may be used is 5-40 weight % of the total weight of the total components, and more preferably 10-30 weight % and most preferably 15-30 weight %.

Optionally, it may be beneficial in certain embodiments to use a reactive monomer compound in the compositions according to the invention. Inclusion of reactive monomers in the composition helps to increase the flexibility of the uncured and cured film. Glycidyl ethers containing two or more glycidyl ether groups are examples of reactive monomers that can be used. Compounds with two or more functional groups are preferred and diethylene glycol diglycidyl ether, propylene glycol diglycidyl ether, polypropylene glycol diglycidyl ether, hexanediol diglycidyl ether, trimethylolpropane triglycidyl ether, pentaerythritol tetraglycidyl ether, and the like are cited as examples. The glycidyl ethers can be used alone or as mixtures of two or more. Trimethylolpropane triglycidyl ether and polypropylene glycol diglycidyl ether are preferred examples of reactive monomers that can be used in the invention. Aliphatic and aromatic monofunctional and/or polyfunctional oxetane compounds are another group of optional reactive monomers that can be used in the present invention. Specific examples of the aliphatic or aromatic oxetane reactive monomers that can be used include 3-ethyl-3-hydroxymethyloxetane, 3-ethyl-3-phenoxymethyloxetane, xylylene dioxetane, bis(3-ethyl-3-oxetanylmethyl)ether, and the like. These monofunctional and/or polyfunctional oxetane compounds can be used alone or as mixtures of two or more. Alicyclic epoxy compounds can also be used as reactive monomer in this invention and 3,4-epoxycyclohexylmethyl methacrylate and 3,4-epoxycyclohexylmethyl-3′,4′-epoxycyclohexane carboxylate may be cited as examples. When an optional reactive monomer is used, the amount that may be used is 1-20 weight % of the total weight of the components, more preferably 2-15 weight % and most preferably 4-10 weight %.

Optionally, it may be useful to include photosensitizer compounds in the composition so that more ultraviolet radiation is absorbed and the energy that has been absorbed is transferred to the photoacid generator. Consequently, the process time for exposure is decreased. Anthracene and N-alkyl carbazole compounds are examples of photosensitizers that can be used in the invention. Anthracene compounds with alkoxy groups at positions 9 and 10 (9,10-dialkoxyanthracenes) are preferred photosensitizers (G). C₁ to C₄ alkoxy groups such as methoxy, ethoxy, propoxy, and butoxy groups are cited as the preferred alkoxy groups. The 9,10-dialkoxyanthracenes can also have substituent groups. Halogen atoms such as fluorine atoms, chlorine atoms, bromine atoms, and iodine atoms, C₁ to C₄ alkyl groups such as methyl groups, ethyl groups, and propyl groups, sulfonic acid groups, sulfonate ester groups, carboxylic acid alkyl ester groups, and the like are cited as examples of substituent groups. C₁ to C₄ alkyls, such as methyl, ethyl, and propyl, are given as examples of the alkyl moiety in the sulfonic acid alkyl ester groups and carboxylic acid alkyl ester groups. The substitution position of these substituent groups is preferably at position 2 of the anthracene ring system. 9,10-Dimethoxyanthracene, 9,10-diethoxyanthracene, 9,10-dipropoxyanthracene, 9,10-dimethoxy-2-ethylanthracene, 9,10-diethoxy-2-ethylanthracene, 9,10-dipropoxy-2-ethylanthracene, 9,10-dimethoxy-2-chloroanthracene, 9,10-dimethoxyanthracene-2-sulfonic acid, 9,10-dimethoxyanthracene-2-sulfonic acid methyl ester, 9,10-diethoxyanthracene-2-sulfonic acid methyl ester, 9,10-dimethoxyanthracene 2-carboxylic acid, 9,10-dimethoxyanthracene-2-carb-oxylic acid methyl ester, and the like can be cited as specific examples of the 9,10-dialkoxyanthracenes that can be used in the present invention. Examples of N-alkyl carbazole compounds useful in the invention include N-ethyl carbazole, N-ethyl-3-formyl-carbazole, 1,4,5,8,9-pentamethyl-carbazole, N-ethyl-3,6-dibenzoyl-9-ethylcarbazole and 9,9′-diethyl-3,3′-bicarbazole. The sensitizer compounds can be used alone or in mixtures of two or more. When used, optional photosensitizer component may be present in an amount that is 05 to 4.0 weight % relative to the PAG and it is more preferred to use 0.5-3.0 weight % and most preferred to use 1-2.5 weight %.

Examples of optional adhesion promoting compounds that can be used in the invention include: 3-glycidoxypropyltrimethoxysilane, 3-glycidoxypropyltriethoxysilane, 3-mercaptopropyltrimethoxysilane, vinyltrimethyoxysilane, [3-(methacryloyloxy)propyl]tri-methoxysilane, and the like.

Optionally, it may be useful to include compounds that absorb actinic rays and have an absorbance coefficient at 365 nm of 15 L/g·cm or higher. Such compounds can be used to provide a relief image cross section that has a reverse tapered shape such that the imaged material at the top of the image is wider than the imaged material at the bottom of the image. Benzophenone compounds such as 2,4-dihydroxybenzophenone and 2,2′,4,4′-tetrahydroxybenzophenone, salicylic acid compounds such as phenyl salicylate and 4-t-butylphenyl salicylate, phenylacrylate compounds such as ethyl-2-cyano-3,3-diphenylacrylate, and 2′-ethylhexyl-2-cyano-3,3-diphenylacrylate, benzotriazole compounds such as 2-(2-hydroxy-5-methylphenyl)-2H-benzotriazole, and 2-(3-t-butyl-2-hydroxy-5-methylphenyl)-5-chloro-2H-benzotriazole, azo dyes such as Sudan Orange G, coumarin compounds such as 4-methyl-7-diethylamino-1-benzopyran-2-one, thioxanthone compounds such as diethylthioxanthone, stilbene compounds, naphthalic acid compounds, and the like are cited as specific examples of the compounds that can be used in the present invention either singly or as mixtures.

Optionally, an organic aluminum compound can be used in the present invention as an ion-gettering agent. There are no special restrictions on the organic aluminum compound as long as it is a compound that has the effect of adsorbing the ionic materials remaining in the cured product. Alkoxyaluminum compounds such as tris-methoxyaluminum, tris-ethoxyaluminum, tris-isopropoxyaluminum, isopropoxydiethoxyaluminum, and tris-butoxyaluminum, phenoxyaluminum compounds such as tris-phenoxyaluminum and tris-para-methylphenoxyaluminum, tris-acetoxyaluminum, tris-aluminum stearate, tris-aluminum butyrate, tris-aluminum propionate, tris-aluminum acetylacetonate, tris-aluminum tolylfluoroacetylacetate, tris-aluminum ethylacetoacetate, aluminum diacetylacetonatodipivaloylmethanate, aluminum diisopropoxy(ethylacetoacetate), and the like are given as specific examples. These components can be used alone or as a combination of two or more components and they are used when it is necessary to alleviate detrimental effects of ions derived from the above-mentioned photoacid generator compounds.

In addition, optional inorganic fillers such as barium sulfate, barium titanate, silicon oxide, amorphous silica, talc, clay, magnesium carbonate, calcium carbonate, aluminum oxide, aluminum hydroxide, montmorillonite clays, and mica powder and various metal powders such as silver, aluminum, gold, iron, CuBiSr alloys, and the like can be used in the present invention. The content of inorganic filler may be 0.1 to 80 weight % of the composition. Likewise, organic fillers such as polymethylmethacrylate, rubber, fluoropolymers, crosslinked epoxies, polyurethane powders and the like can be similarly incorporated.

When necessary, various materials such as crosslinking agents, thermoplastic resins, coloring agents, thickeners, and agents that promote or improve adhesion can be further used in the present invention. Crosslinking agents can include, for example, methoxylated melamine, butoxylated melamine, and alkoxylated glycouril compounds. CYMEL 303 from Cytec Industries, West Paterson, N.J., is a specific example of a suitable methoxylated melamine compound. POWDERLINK 1174 from Cytec Industries, West Paterson, N.J. is a specific example of an alkoxylated glycouril compound. Polyether sulfone, polystyrene, polycarbonate, and the like are cited as examples of thermoplastic resins; phthalocyanine blue, phthalocyanine green, iodine green, crystal violet, titanium oxide, carbon black, naphthalene black, and the like are cited as examples of coloring agents; asbestos, orben, bentonite, and montomorillonite are cited as examples of thickeners and silicone-containing, fluorine-containing, and polymeric defoaming agents are cited as examples of defoaming agents. When these additives and the like are used, their general content in the composition of the present invention is 0.05 to 10 weight % each, but this can be increased or decreased as needed in accordance with the application objective.

The composition of the present invention can be prepared by combining the four essential components and any of the above optional components, mixing uniformly, dissolving, dispersing, and the like with a roll mill, paddle mixer, or similar devices known in the compounding art. It is particularly preferred that components are diluted with solvent and adjusted to a solution viscosity appropriate to the intended use of the composition. The materials are then applied to a substrate and manufactured and cured using known processes into the desired shapes or articles. Substrate materials that can be used include, but are not limited to, silicon, silicon dioxide, silicon nitride, alumina, glass, glass-ceramics, gallium arsenide, indium phosphide, copper, aluminum, nickel, iron, steel, copper-silicon alloys, indium-tin oxide coated glass, organic films such as polyimide and polyester, any substrate bearing patterned areas of metal, semiconductor, and insulating materials, and the like.

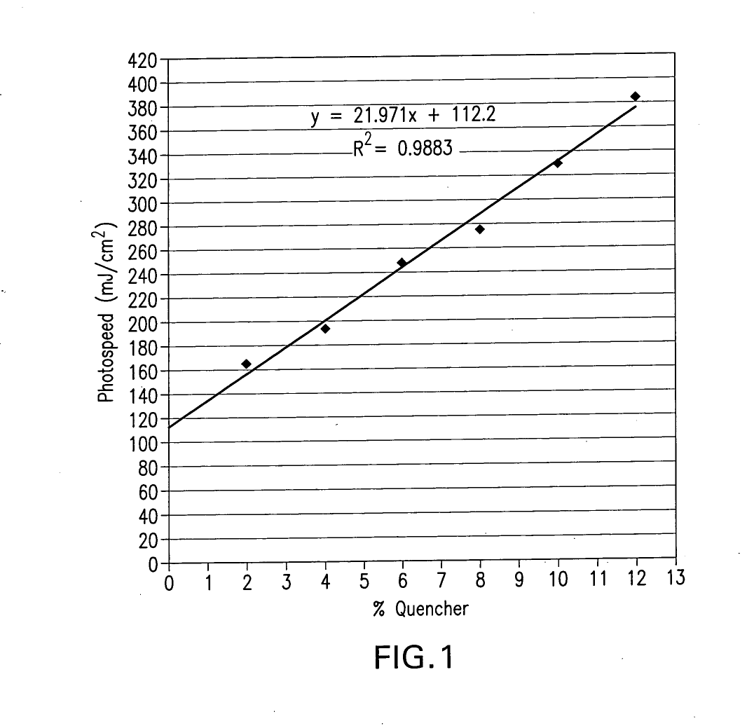

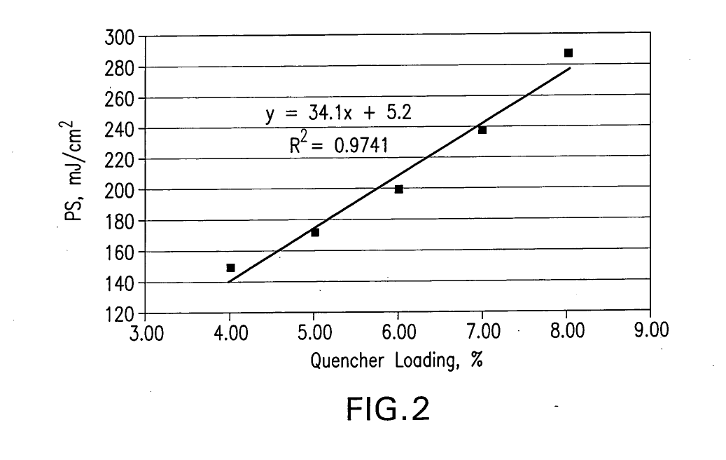

The invention also encompasses a method for controlling photospeed of a chemically amplified negative photoresist. This method comprises the basic steps of (1) providing a negative photoresist based on the above formulations, and (2) selecting a desired photospeed for the negative photoresist and adjusting the amount of the photolabile quencher generator in the photoresist composition to achieve the desired photospeed. As shown in FIGS. 1 and 2, photospeed of a specific formulation of negative photoresist increases in a nearly linear fashion as the amount of photolabile quencher generator is increased. As explained in more detail in the following examples, it is possible to establish a predictable relationship between amount of photolabile quencher load and photospeed for any particular negative photoresist, and adjust the photospeed of the resist based on the specific manufacturing or product needs using this relationship.

In terms of utility, the invention offers the advantage of modulation of the photospeed of the epoxy composition in order to improve the shelf-life of the composition, and to improve the photoimaging capability of the cured imaged product.

### EXAMPLES

The present invention is further described in detail by means of the following Examples. All parts and percentages are by weight and all temperatures are degrees Celsius unless explicitly stated otherwise. For all examples listed below, quencher loading is reported as percent of PAG loading

### Examples 1 and 2

### Effect of Quencher on Photospeed of an Epoxy Photoresist

Examples 1 and 2 below describe use of an aryl sulfonium salt quencher and tris[4[(acetylphenyl)thio]phenyl]sulfonium salt of 10-camphorsulfonic acid to modulate photospeed of an epoxy photoresist. The results are shown graphically in FIGS. 1 and 2.

### Example 1a

### 2% Photospeed Quencher in an Epoxy Photoresist

80.015 grams of an epoxidized bisphenol-A novolac resin (Nippon Kayaku, Tokyo, Japan), 28.206 grams a formaldehyde polymer with (chloromethly)oxirane and phenol resin (Nippon Kayaku, Tokyo, Japan), 2.256 grams diglycidyl ether of propylene glycol (Asahi Denka, Tokyo, Japan), 2.256 grams of glycidoxypropyl trimethoxysilane (Dow Corning, Midland, Mich.), 0.090 grams of Fluor-N 562 (Cytonix, Beltsville, Md.) surface leveling agent, 0.564 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF, Ludwigshafen, Germany), 0.011 grams of an aryl sulfonium salt of camphor sulfonic acid, specifically a triphenylsulfonium salt of 10-camphorsulfonic acid, 25.834 grams of cyclopentanone and 1.830 grams of gamma-butyrolactone were charged into a 500 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 50 microns on a 6 inch silicon wafer and subsequently baked at 95° C. for 5 minutes on a proximity hotplate. The film was subsequently photoexposed to 550 mJ/cm² total dose, using an EVG 620 photoaligner equipped with broad-band i-line irradiation, an i-line cutoff filter, and a multistep transmission mask. Following exposure, the wafer was post-exposure two baked at 65° C./1 min, followed by 95° C./2 min and then cooled to room temperature. Solvent development for 8 minutes in PGMEA produced a patterned wafer. The dose required to produce a 10 micron line/space feature at 1:1 pitch was 165 mJ/cm².

### Example 1b

### 4% Photospeed Quencher in an Epoxy Photoresist

80.007 grams of an epoxidized bisphenol-A novolac resin, 28.203 grams a formaldehyde polymer with (chloromethly)oxirane and phenol resin, 2.256 grams diglycidyl ether of propylene glycol, 2.256 grams of glycidoxypropyl trimethoxysilane, 0.090 grams of Fluor-N 562 surface leveling agent, 0.564 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid, 0.023 grams of an aryl sulfonium salt of camphor sulfonic acid, specifically a triphenylsulfonium salt of 10-camphorsulfonic acid, 25.835 grams of cyclopentanone and 1.830 grams of gamma-Butyrolactone were charged into a 500 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 50 microns on a 6 inch silicon wafer and subsequently baked at 95° C. for 5 minutes on a proximity hotplate. The film was subsequently photoexposed to 550 mJ/cm² total dose, using an EVG 620 Photoaligner equipped with broad-band i-line irradiation, an i-line cutoff filter, and a multistep transmission mask. Following exposure, the wafer was post-exposure two baked at 65° C./1 min, followed by 95° C./2 min and then cooled to room temperature. Solvent development for 8 minutes in PGMEA produced a patterned wafer. The dose required to produce a 10 micron line/space feature at 1:1 pitch was 193 mJ/cm².

### Example 1c

### 6% Photospeed Quencher in an Epoxy Photoresist

79.999 grams of an epoxidized bisphenol-A novolac resin, 28.201 grams a formaldehyde polymer with (chloromethly)oxirane and phenol resin, 2.256 grams diglycidyl ether of propylene glycol, 2.256 grams of glycidoxypropyl trimethoxysilane, 0.090 grams of Fluor-N 562 surface leveling agent, 0.564 grams of an arylsulfonium salt of 1,1,2,2,3,3,4,4-nonafluoro-1 butanesulfonic acid, specifically Tris[4-[(acetylphenyl)thio]phenyl]sulfonium salt of 1,1,2,2,3,3,4,4-nonafluoro-1-butanesulfonic acid, 0.034 grams of an aryl sulfonium salt of camphor sulfonic acid, specifically a triphenylsulfonium salt of 10-camphorsulfonic acid, 25.836 grams of cyclopentanone and 1.830 grams of gamma-Butyrolactone were charged into a 500 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 50 microns on a 6 inch silicon wafer and subsequently baked at 95° C. for 5 minutes on a proximity hotplate. The film was subsequently photoexposed to 550 mJ/cm² total dose, using an EVG 620 Photoaligner equipped with broad-band i-line irradiation, an i-line cutoff filter, and a multistep transmission mask. Following exposure, the wafer was post-exposure two baked at 65° C./1 min, followed by 95° C./2 min and then cooled to room temperature. Solvent development for 8 minutes in PGMEA produced a patterned wafer. The dose required to produce a 10 micron line/space feature at 1:1 pitch was 248 mJ/cm².

### Example 1d

### 8% Photospeed Quencher in an Epoxy Photoresist

79.991 grams of an epoxidized bisphenol-A novolac resin, 28.198 grams a formaldehyde polymer with (chloromethly)oxirane and phenol resin, 2.256 grams diglycidyl ether of propylene glycol, 2.256 grams of glycidoxypropyl trimethoxysilane, 0.090 grams of Fluor-N 562 surface leveling agent, 0.564 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid, 0.045 grams of an aryl sulfonium salt of camphor sulfonic acid, specifically a triphenylsulfonium salt of 10-camphorsulfonic acid, 25.837 grams of cyclopentanone and 1.830 grams of gamma-Butyrolactone were charged into a 500 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 50 microns on a 6 inch silicon wafer and subsequently baked at 95° C. for 5 minutes on a proximity hotplate. The film was subsequently photoexposed to 550 mJ/cm² total dose, using an EVG 620 Photoaligner equipped with broad-band i-line irradiation, an i-line cutoff filter, and a multistep transmission mask. Following exposure, the wafer was post-exposure two baked at 65° C./1 min, followed by 95° C./2 min and then cooled to room temperature. Solvent development for 8 minutes in PGMEA produced a patterned wafer. The dose required to produce a 10 micron line/space feature at 1:1 pitch was 275 mJ/cm².

### Example 1e

### 10% Photospeed Quencher in an Epoxy Photoresist

79.983 grams of an epoxidized bisphenol-A novolac resin, 28.195 grams a formaldehyde polymer with (chloromethly)oxirane and phenol resin, 2.256 grams diglycidyl ether of propylene glycol, 2.256 grams of glycidoxypropyl trimethoxysilane, 0.090 grams of Fluor-N 562 surface leveling agent, 0.564 grams of an arylsulfonium salt of 1,1,2,2,3,3,4,4-nonalluoro-1-butanesulfonic acid, specifically Tris[4-[(acetylphenyl)thio]phenyl]sulfonium salt of 1,1,2,2,3,3,4,4-nonafluoro-1-butanesulfonic acid, 0.056 grams of an aryl sulfonium salt of camphor sulfonic acid, specifically a triphenylsulfonium salt of 10-camphorsulfonic acid, 25.838 grams of cyclopentanone and 1.830 grams of gamma-Butyrolactone were charged into a 500 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 50 microns on a 6 inch silicon wafer and subsequently baked at 95° C. for 5 minutes on a proximity hotplate. The film was subsequently photoexposed to 550 mJ/cm² total dose, using an EVG 620 Photoaligner equipped with broad-band i-line irradiation, an i-line cutoff filter, and a multistep transmission mask. Following exposure, the wafer was post-exposure two baked at 65° C./1 min, followed by 95° C./2 min and then cooled to room temperature. Solvent development for 8 minutes in PGMEA produced a patterned wafer. The dose required to produce a 10 micron line/space feature at 1:1 pitch was 275 mJ/cm².

FIG. 1 shows a graph of the results of Examples 1a-1e. As shown in FIG. 1, photospeed increases with increasing amounts of quencher.

### Example 2a

### 4% Photospeed Quencher in an Epoxy Photoresist

74.76 grams of an epoxidized bisphenol-A novolac resin (Nippon Kayaku), 0.3738 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF), 0.015 grams of an aryl sulfonium salt of camphor sulfonic acid, specifically a triphenyl sulfonium salt of 10-camphorsulfonic acid, and 24.85 grams of gamma-Butyrolactone were charged into a 250 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 100 microns on a 6 inch silicon wafer and subsequently baked at 65° C./8 min then 95° C./45 min on a proximity hotplate. The film was subsequently photoexposed to 300 mJ/cm² total dose, using an EVG 620 Photoaligner equipped with broad-band i-line irradiation, an i-line cutoff filter, and a multistep transmission mask. Following exposure, the wafer was post-exposure two baked at 65° C./4 min, followed by 95° C./10 min and then cooled to room temperature. Solvent development for 6 minutes in PGMEA produced a patterned wafer. The dose required to produce a 10 micron line/space feature at 1:1 pitch was 150 mJ/cm².

### Example 2b

### 5% Photospeed Quencher in an Epoxy Photoresist

74.76 grams of an epoxidized bisphenol-A novolac resin (Nippon Kayaku), 0.3738 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF), 0.019 grams of an aryl sulfonium salt of camphor sulfonic acid, specifically a triphenylsulfonium salt of 10-camphorsulfonic acid, and 24.85 grams of gamma-Butyrolactone were charged into a 250 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 100 microns on a 6 inch silicon wafer and subsequently baked at 65° C./8 min then 95° C./45 min on a proximity hotplate. The film was subsequently photoexposed to 300 mJ/cm² total dose, using an EVG 620 Photoaligner equipped with broad-band i-line irradiation, an i-line cutoff filter, and a multistep transmission mask. Following exposure, the wafer was post-exposure two baked at 65° C./4 min, followed by 95° C./10 min and then cooled to room temperature. Solvent development for 6 minutes in PGMEA produced a patterned wafer. The dose required to produce a 10 micron line/space feature at 1:1 pitch was 173 mJ/cm².

### Example 2c

### 6% Photospeed Quencher in an Epoxy Photoresist

74.77 grams of an epoxidized bisphenol-A novolac resin (Nippon Kayaku), 0.3738 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF), 0.022 grams of an aryl sulfonium salt of camphor sulfonic acid, specifically a triphenylsulfonium salt of 10-camphorsulfonic acid, and 24.85 grams of gamma-Butyrolactone were charged into a 250 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 100 microns on a 6 inch silicon wafer and subsequently baked at 65° C./8 min then 95° C./45 min on a proximity hotplate. The film was subsequently photoexposed to 400 mJ/cm² total dose, using an EVG 620 Photoaligner equipped with broad-band i-line irradiation, an i-line cutoff filter, and a multistep transmission mask. Following exposure, the wafer was post-exposure two baked at 65° C./4 min, followed by 95° C./10 min and then cooled to room temperature. Solvent development for 6 minutes in PGMEA produced a patterned wafer. The dose required to produce a 10 micron line/space feature at 1:1 pitch was 200 mJ/cm².

### Example 2d

### 7% Photospeed Quencher in an Epoxy Photoresist

74.77 grams of an epoxidized bisphenol-A novolac resin (Nippon Kayaku), 0.3738 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF), 0.026 grams of an aryl sulfonium salt of camphor sulfonic acid, specifically a triphenylsulfonium salt of 10-camphorsulfonic acid, and 24.85 grams of gamma-Butyrolactone were charged into a 250 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 100 microns on a 6 inch silicon wafer and subsequently baked at 65° C./8 min then 95° C./45 min on a proximity hotplate. The film was subsequently photoexposed to 500 mJ/cm² total dose, using an EVG 620 Photoaligner equipped with broad-band i-line irradiation, an i-line cutoff filter, and a multistep transmission mask. Following exposure, the wafer was post-exposure two baked at 65° C./4 min, followed by 95° C./10 min and then cooled to room temperature. Solvent development for 6 minutes in PGMEA produced a patterned wafer. The dose required to produce a 10 micron line/space feature at 1:1 pitch was 238 mJ/cm².

### Example 2e

### 8% Photospeed Quencher in an Epoxy Photoresist

74.77 grams of an epoxidized bisphenol-A novolac resin (Nippon Kayaku), 0.3738 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF), 0.030 grams of an aryl sulfonium salt of camphor sulfonic acid, specifically a triphenylsulfonium salt of 10-camphorsulfonic acid, and 24.85 grams of gamma-Butyrolactone were charged into a 250 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 100 microns on a 6 inch silicon wafer and subsequently baked at 65° C./8 min then 95° C./45 min on a proximity hotplate. The film was subsequently photoexposed to 600 mJ/cm² total dose, using an EVG 620 Photoaligner equipped with broad-band i-line irradiation, an i-line cutoff filter, and a multistep transmission mask. Following exposure, the wafer was post-exposure two baked at 65° C./4 min, followed by 95° C./10 min and then cooled to room temperature. Solvent development for 6 minutes in PGMEA produced a patterned wafer. The dose required to produce a 10 micron line/space feature at 1:1 pitch was 228 mJ/cm².

FIG. 2 shows a graph of the results of Examples 2a-2e. As shown in FIG. 2, photospeed increases with increasing amounts of quencher.

### Example 3

### Modulation of Photospeed of an Epoxy Photoresist while Maintaining Constant Absorbance

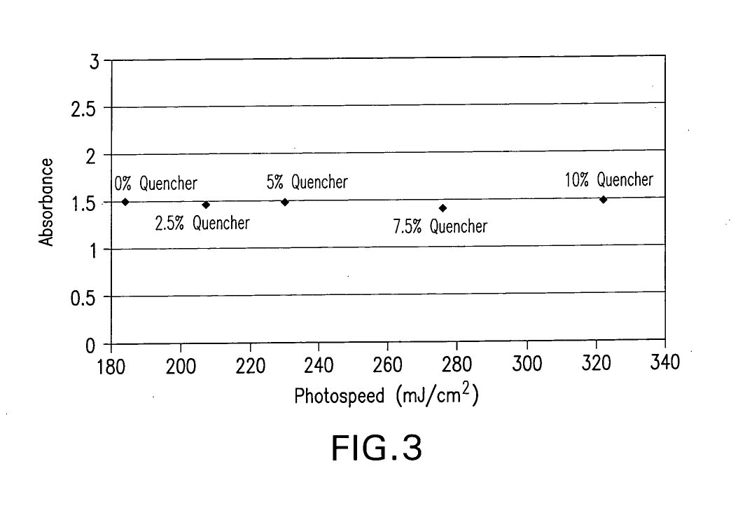

Example 3 below describes use of an aryl sulfonium salt quencher, tris[4[(acetylphenyl)thio]phenyl]sulfonium salt of 10-camphorsulfonic acid, in the modulation of photospeed of an epoxy photoresist while maintaining constant absorbance. In Example 3, the total weight of PAG and quencher is held constant, and the % PAG and quencher loading is reported as a percent of solids. The results are shown graphically in FIG. 3.

### Example 3a

### 0% Quencher Loading and 100% PAG Loading

38.024 grams of an epoxidized bisphenol-A novolac resin (Nippon Kayaku), 16.746 grams a formaldehyde polymer with (chloromethly)oxirane and phenol resin (Nippon Kayaku), 16.746 g cycloaliphatic epoxy resin, EHPE 3150 (Diacel, Osaka, Japan) 3.045 grams diglycidyl ether of propylene glycol (Asahi Denka), 1.522 grams of glycidoxypropyl trimethoxysilane (Dow Corning), 0.046 grams of Fluor-N 562 (Cytonix) surface leveling agent, 0.381 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF), and 23.089 grams of cyclopentanone were charged into a 500 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 50 microns on a 6 inch silicon wafer and subsequently baked at 95° C. for 5 minutes on a proximity hotplate. The film was subsequently photoexposed to 460 mJ/cm² total dose, using an EVG 620 Photoaligner equipped with broad-band i-line irradiation, an i-line cutoff filter, and a multistep transmission mask. Following exposure, the wafer was post-exposure two baked at 65° C./1 min, followed by 95° C./2 min and then cooled to room temperature. Solvent development for 8 minutes in PGMEA produced a patterned wafer. The dose required to produce a 10 micron line/space feature at 1:1 pitch was 184 mJ/cm². The film had an absorbance of 1.50 at 322 nm.

### Example 3b

### 2.5% Quencher Loading and 97.5% PAG Loading

38.014 grams of an epoxidized bisphenol-A novolac resin (Nippon Kayaku), 16.746 grams a formaldehyde polymer with (chloromethly)oxirane and phenol resin (Nippon Kayaku), 16.746 g cycloaliphatic epoxy resin, EHPE 3150 (Diacel) 3.045 grams diglycidyl ether of propylene glycol (Asahi Denka), 1.522 grams of glycidoxypropyl trimethoxysilane (Dow Corning), 0.046 grams of Fluor-N 562 (Cytonix) surface leveling agent, 0.371 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF), 0.010 grams of an aryl sulfonium salt of camphor sulfonic acid, specifically a triphenylsulfonium salt of 10-camphorsulfonic acid, and 23.089 grams of cyclopentanone were charged into a 500 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 50 microns on a 6 inch silicon wafer and subsequently baked at 95° C. for 5 minutes on a proximity hotplate. The film was subsequently photoexposed to 460 mJ/cm² total dose, using an EVG 620 Photoaligner equipped with broad-band i-line irradiation, an i-line cutoff filter, and a multistep transmission mask. Following exposure, the wafer was post-exposure two baked at 65° C./1 min, followed by 95° C./2 min and then cooled to room temperature. Solvent development for 8 minutes in PGMEA produced a patterned wafer. The dose required to produce a 10 micron line/space feature at 1:1 pitch was 207 mJ/cm². The film had an absorbance of 1.47 at 322 nm.

### Example 3c

### 5.0% Quencher Loading and 95.0% PAG Loading

38.014 grams of an epoxidized bisphenol-A novolac resin (Nippon Kayaku), 16.746 grams a formaldehyde polymer with (chloromethly)oxirane and phenol resin (Nippon Kayaku), 16.746 g cycloaliphatic epoxy resin, EHPE 3150 (Diacel) 3.045 grams diglycidyl ether of propylene glycol (Asahi Denka), 1.522 grams of glycidoxypropyl trimethoxysilane (Dow Corning), 0.046 grams of Fluor-N 562 (Cytonix) surface leveling agent, 0.362 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF), 0.019 grams of an aryl sulfonium salt of camphor sulfonic acid, specifically a triphenylsulfonium salt of 10-camphorsulfonic acid, and 23.089 grams of cyclopentanone were charged into a 500 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 50 microns on a 6 inch silicon wafer and subsequently baked at 95° C. for 5 minutes on a proximity hotplate. The film was subsequently photoexposed to 460 mJ/cm² total dose, using an EVG 620 Photoaligner equipped with broad-band i-line irradiation, an i-line cutoff filter, and a multistep transmission mask. Following exposure, the wafer was post-exposure two baked at 65° C./1 min, followed by 95° C./2 min and then cooled to room temperature. Solvent development for 8 minutes in PGMEA produced a patterned wafer. The dose required to produce a 10 micron line/space feature at 1:1 pitch was 230 mJ/cm². The film had an absorbance of 1.48 at 322 nm.

### Example 3d

### 7.5% Quencher Loading and 92.5% PAG Loading

38.014 grams of an epoxidized bisphenol-A novolac resin (Nippon Kayaku), 16.746 grams a formaldehyde polymer with (chloromethly)oxirane and phenol resin (Nippon Kayaku), 16.746 g cycloaliphatic epoxy resin, EHPE 3150 (Diacel) 3.045 grams diglycidyl ether of propylene glycol (Asahi Denka), 1.522 grams of glycidoxypropyl trimethoxysilane (Dow Corning), 0.046 grams of Fluor-N 562 (Cytonix) surface leveling agent, 0.352 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF), 0.029 grams of an aryl sulfonium salt of camphor sulfonic acid, specifically a triphenylsulfonium salt of 10-camphorsulfonic acid, and 23.089 grams of cyclopentanone were charged into a 500 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 50 microns on a 6 inch silicon wafer and subsequently baked at 95° C. for 5 minutes on a proximity hotplate. The film was subsequently photoexposed to 460 mJ/cm² total dose, using an EVG 620 Photoaligner equipped with broad-band i-line irradiation, an i-line cutoff filter, and a multistep transmission mask. Following exposure, the wafer was post-exposure two baked at 65° C./1 min, followed by 95° C./2 min and then cooled to room temperature. Solvent development for 8 minutes in PGMEA produced a patterned wafer. The dose required to produce a 10 micron line/space feature at 1:1 pitch was 276 mJ/cm². The film had an absorbance of 1.41 at 322 nm.

### Example 3e

### 7.5% Quencher Loading and 92.5% PAG Loading

38.014 grams of an epoxidized bisphenol-A novolac resin (Nippon Kayaku), 16.746 grams a formaldehyde polymer with (chloromethly)oxirane and phenol resin (Nippon Kayaku), 16.746 g cycloaliphatic epoxy resin, EHPE 3150 (Diacel) 3.045 grams diglycidyl ether of propylene glycol (Asahi Denka), 1.522 grams of glycidoxypropyl trimethoxysilane (Dow Corning), 0.046 grams of Fluor-N 562 (Cytonix) surface leveling agent, 0.343 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF), 0.038 grams of an aryl sulfonium salt of camphor sulfonic acid, specifically a triphenylsulfonium salt of 10-camphorsulfonic acid, and 23.089 grams of cyclopentanone were charged into a 500 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 50 microns on a 6 inch silicon wafer and subsequently baked at 95° C. for 5 minutes on a proximity hotplate. The film was subsequently photoexposed to 460 mJ/cm² total dose, using an EVG 620 Photoaligner equipped with broad-band i-line irradiation, an i-line cutoff filter, and a multistep transmission mask. Following exposure, the wafer was post-exposure two baked at 65° C./1 min, followed by 95° C./2 min and then cooled to room temperature. Solvent development for 8 minutes in PGMEA produced a patterned wafer. The dose required to produce a 10 micron line/space feature at 1:1 pitch was 322 mJ/cm². The film had an absorbance of 1.48 at 322 nm.

FIG. 3 shows a graph of the results of Examples 3a-3e. As shown in FIG. 3, absorbance remains constant as photospeed increases.

### Example 4

### Modulation of Photospeed of an Epoxy Photoresist Using DTBPIC

Example 4 describes use of the aryl iodonium salt quencher di(t-butyl phenyl) iodonium salt of 10-camphorsulfonic acid (DTBPIC) to modulate photospeed of an epoxy photoresist.

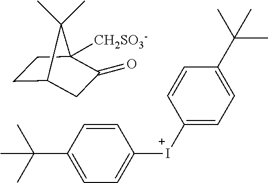

### Example 4a

### 0% Iodonium Photospeed Quencher in an Epoxy Photoresist

37.469 grams of an epoxidized bisphenol-A novolac resin (Nippon Kayaku), 0.1869 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF), and 9.82 grams of gamma-Butyrolactone were charged into a 100 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 100 microns on a 6 inch silicon wafer and subsequently baked at 65° C./8 min then 95° C./45 min on a proximity hotplate. The film was subsequently photoexposed using an EVG 620 Photoaligner equipped with broad-band i-line irradiation, an i-line cutoff filter, and a multistep transmission mask. Following exposure, the wafer was post-exposure two baked at 65° C./4 min, followed by 95° C./10 min and then cooled to room temperature. Solvent development for 6 minutes in PGMEA produced a patterned wafer. The dose required to produce a 10 micron line/space feature at 1:1 pitch was 70 mJ/cm².

### Example 4b

### 5% Iodonium Photospeed Quencher in an Epoxy Photoresist

37.469 grams of an epoxidized bisphenol-A novolac resin (Nippon Kayaku), 0.1869 grams of an arylsulfonium salt of 1,1,2,2,3,3,4,4-nonafluoro-1-butanesulfonic acid, specifically Tris[4-[(acetylphenyl)thio]phenyl]sulfonium salt of 1,1,2,2,3,3,4,4-nonafluoro-1-butanesulfonic acid (BASF), 0.009 grams of an aryl iodonium salt of camphor sulfonic acid, specifically di(t-butyl phenyl) iodonium salt of 10-camphorsulfonic acid (Hamford, Stratford, Conn.), and 9.82 grams of gamma-Butyrolactone were charged into a 100 ml bottle. The mixture was rolled with the application of heat from an IR lamp in order to dissolve all of the components into a homogeneous solution. The resist solution was filtered through a 5 micron absolute polypropylene filter. 10 mL of resist was spin-coated to 100 microns on a 6 inch silicon wafer and subsequently baked at 65° C./8 min then 95° C./45 min on a proximity hotplate. The film was subsequently photoexposed using an EVG 620 Photoaligner equipped with broad-band i-line irradiation, an i-line cutoff filter, and a multistep transmission mask. Following exposure, the wafer was post-exposure two baked at 65° C./4 min, followed by 95° C./10 min and then cooled to room temperature. Solvent development for 6 minutes in PGMEA produced a patterned wafer. The dose required to produce a 10 micron line/space feature at 1:1 pitch was 200 mJ/cm².

While the invention has been described above with reference to specific embodiments thereof, it is apparent that many changes, modifications, and variation can be made without departing from the inventive concept disclosed herein. Accordingly, it is intended to embrace all such changes, modifications, and variations that fall within the spirit and broad scope of the appended claims. All patent applications, patents, and other publications cited herein are incorporated by reference in their entirety.

What is claimed is:

1. An epoxy film composition, comprising:
novolac resin;
solvent;
a photoacid generator having the structure
A⁺B⁻
and having a pKa of −5 or less;
a photolabile quencher generator having the structure
C⁺D⁻
and having a pKa greater than −10;
wherein B⁻ and D⁻ are different;
wherein the amount of said photoacid generator ranges from 0.1 to 10 wt %, based on the total weight of said novolac resin; and
wherein the amount of said photolabile quencher generator ranges from 0.1 to 20 wt %, based on the total weight of said photoacid generator.

2. The composition of claim 1, wherein said novolac resin is an epoxidized bisphenol-A novolac resin.

3. The composition of claim 2, wherein said novolac resin comprises from about 40 to about 80 wt % of total solids, based on the total weight of said composition.

4. The composition of claim 1, wherein said solvent is selected from the group consisting of acetone, 2-butanone, 2-pentanone, 3-pentanone, methyl isobutyl ketone, methyl t-butyl ketone, cyclopentanone, cyclohexanone, dipropylene glycol dimethyl ether, dipropylene glycol diethyl ether, tetrahydrofuran, 1,3-dioxolane, 1,4-dioxane, dimethoxyethane, diglyme, triglyme, ethyl acetate, butyl acetate, butyl cellosolve acetate, carbitol acetate, propylene glycol monomethyl ether acetate, gamma-butyrolactone, toluene, xylene, tetramethylbenzene, octane, decane, anisole, and combinations thereof.

5. The composition of claim 4, wherein said solvent comprises from 10 to 80% by weight, based on the total weight of said composition.

6. The composition of claim 4, wherein said solvent comprises from about 20 to about 60% by weight, based on the total weight of said composition.

7. The composition of claim 1, wherein the A⁺ component of said photoacid generator and said C⁺ component of said photolabile quencher generator are individually selected from the group consisting of aromatic sulfonium cation, aromatic iodonium cation, indolinium cation, and combinations thereof.

8. The composition of claim 1, wherein the A⁺ component of said photoacid generator and said C⁺ component of said photolabile quencher generator are individually selected from the group consisting of (Aryl)₃S⁺, (Aryl)₂(Alkyl)S⁺, (Aryl)(Alkyl)₂S⁺, and (Aryl)₂I⁺ where Aryl is any structure containing at least one aromatic group.

9. The composition of claim 1, wherein the A⁺ component of said first photoacid generator and said C⁺ component of said photolabile quencher generator are individually selected from the group consisting of

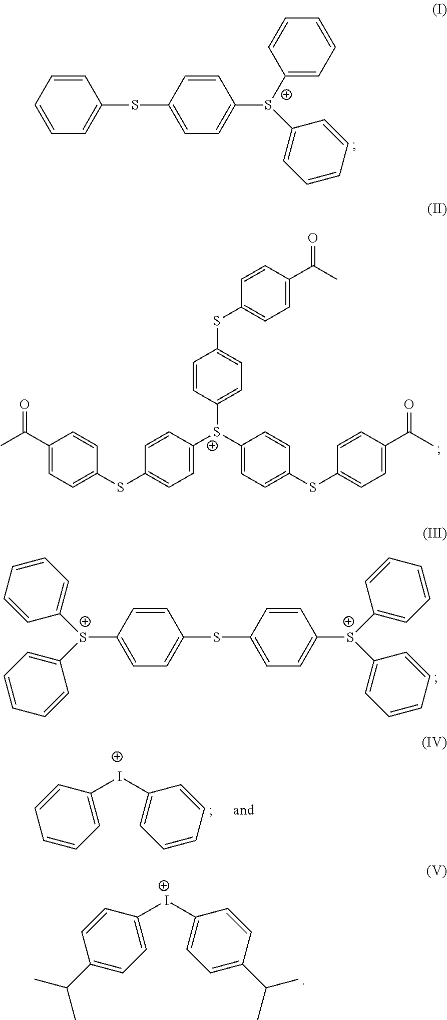

10. The composition of claim 1, wherein the B⁻ component is selected from the group consisting of SbF₆⁻, PF₆⁻, AsF₆⁻, (CF₃SO₂)₃C⁻, (CF₃CF₂)₃PF₃⁻, (C₆F₅)₄B⁻, and CF₃SO₃⁻.

11. The composition of claim 1, wherein the amount of said photoacid generator ranges from 0.5 to 5 wt %, based on the total weight of said novolac resin.

12. The composition of claim 1, wherein the D⁻ component is RSO₃⁻ where R is an alkyl group have 1-10 carbon atoms.

13. The composition of claim 1, wherein said D− component is selected from the group consisting of CH₃SO₃⁻, C₂H₅SO₃⁻, C₃H₇SO₃⁻, C₄H₉SO₃⁻ and

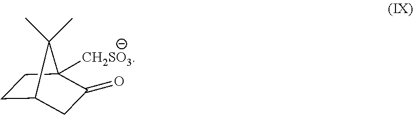

14. The composition of claim 1, wherein said photoacid generator and said photolabile quencher have equivalent or identical extinction coefficients at the wavelength of exposure.

15. The composition of claim 1, wherein the A⁺ component of said photoacid generator and said C⁺ component of said photolabile quencher generator are the same.

16. The composition of claim 1, wherein said photoacid generator has a pKa of −20 or less;

17. The composition of claim 1, wherein said photolabile quencher generator has a pKa of 1 or greater.

18. The composition of claim 1, wherein the amount of said photolabile quencher generator ranges from 1 to 10 wt %, based on the total weight of said photoacid generator.

19. A method for controlling photospeed of a chemically amplified negative photoresist, comprising the steps of:
(a) providing a negative photoresist composition comprising
novolac resin;
solvent;
a photoacid generator having the structure
A⁺B⁻
and having a pKa of −5 or less;
a photolabile quencher generator having the structure
C⁺D⁻
and having a pKa greater than −10;
wherein B⁻ and D⁻ are different;
wherein the amount of said photoacid generator ranges from 0.1 to 10 wt %, based on the total weight of said novolac resin; and
wherein the amount of said photolabile quencher generator ranges from 0.1 to 20 wt %, based on the total weight of said photoacid generator; and
(b) selecting a desired photospeed for said negative photoresist and adjusting the amount of said photolabile quencher generator in said photoresist composition to achieve said desired photospeed.

20. The method of claim 19, wherein said novolac resin is an epoxidized bisphenol-A novolac resin.

21. The method of claim 20, wherein said novolac resin comprises from about 40 to about 80 wt % of total solids, based on the total weight of said composition.

22. The method of claim 19, wherein said solvent is selected from the group consisting of acetone, 2-butanone, 2-pentanone, 3-pentanone, methyl isobutyl ketone, methyl t-butyl ketone, cyclopentanone, cyclohexanone, dipropylene glycol dimethyl ether, dipropylene glycol diethyl ether, tetrahydrofuran, 1,3-dioxolane, 1,4-dioxane, dimethoxyethane, diglyme, triglyme, ethyl acetate, butyl acetate, butyl cellosolve acetate, carbitol acetate, propylene glycol monomethyl ether acetate, gamma-butyrolactone, toluene, xylene, tetramethylbenzene, octane, decane, anisole, and combinations thereof.

23. The method of claim 22, wherein said solvent comprises from 10 to 80% by weight, based on the total weight of said composition.

24. The method of claim 22, wherein said solvent comprises from about 20 to about 60% by weight, based on the total weight of said composition.

25. The method of claim 19, wherein the A⁺ component of said photoacid generator and said C⁺ component of said photolabile quencher generator are individually selected from the group consisting of aromatic sulfonium cation, aromatic iodonium cation, indolinium cation, and combinations thereof.

26. The method of claim 19, wherein the A⁺ component of said photoacid generator and said C⁺ component of said photolabile quencher generator are individually selected from the group consisting of (Aryl)₃S⁺, (Aryl)₂(Alkyl)S⁺, (Aryl)(Alkyl)₂S⁺, and (Aryl)₂I⁺ where Aryl is any structure containing at least one aromatic group.

27. The method of claim 19, wherein the A⁺ component of said first photoacid generator and said C⁺ component of said photolabile quencher generator are individually selected from the group consisting of

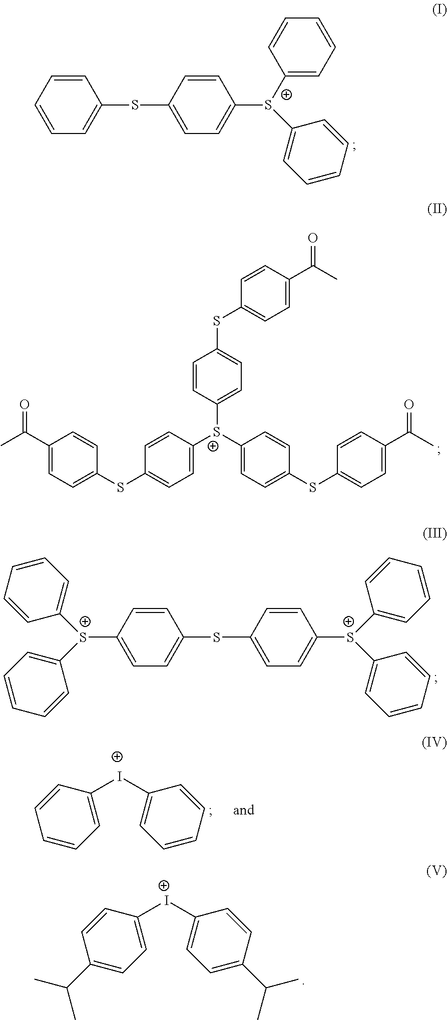

28. The method of claim 19, wherein the B⁻ component is selected from the group consisting of SbF₆⁻, PF₆⁻, AsF₆⁻, (CF₃SO₂)₃C⁻, (CF₃CF₂)₃PF₃⁻, (C₆F₅)₄B⁻, and CF₃SO₃⁻.

29. The method of claim 19, wherein the amount of said photoacid generator ranges from 0.5 to 5 wt %, based on the total weight of said novolac resin.

30. The method of claim 19, wherein the D⁻ component is RSO₃⁻ where R is an alkyl group have 1-10 carbon atoms.

31. The method of claim 19, wherein said D− component is selected from the group consisting of CH₃SO₃⁻, C₂H₅SO₃⁻, C₃H₇SO₃⁻, C₄H₉SO₃⁻ and

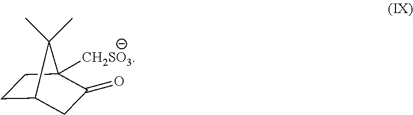

32. The method of claim 19, wherein said photoacid generator and said photolabile quencher have equivalent or identical extinction coefficients at the wavelength of exposure.

33. The method of claim 19, wherein the A⁺ component of said photoacid generator and said C⁺ component of said photolabile quencher generator are the same.

34. The method of claim 19, wherein said photoacid generator has a pKa of −20 or less;

35. The method of claim 19, wherein said photolabile quencher generator has a pKa of 1 or greater.

36. The method of claim 19, wherein the amount of said photolabile quencher generator ranges from 1 to 10 wt %, based on the total weight of said photoacid generator.
